(19) United States
(12) Patent Application Publication
(10) Pub. No.: US 2025/0208480 A1
(43) Pub. Date: Jun. 26, 2025

(54) WAVELENGTH CONVERSION SYSTEM, SOLID-STATE LASER SYSTEM, AND ELECTRONIC DEVICE MANUFACTURING METHOD

(71) Applicant: Gigaphoton Inc., Tochigi (JP)

(72) Inventor: Takayuki OSANAI, Oyama-shi (JP)

(73) Assignee: Gigaphoton Inc., Tochigi (JP)

(21) Appl. No.: 19/075,082

(22) Filed: Mar. 10, 2025

Related U.S. Application Data
(63) Continuation of application No. PCT/JP2022/039779, filed on Oct. 25, 2022.

(51) Int. Cl. G02F 1/35; G03F 7/00; H01S 5/00

(52) U.S. Cl. CPC G02F 1/3507; G02F 1/3503; G03F 7/70025; H01S 5/0092

(57) ABSTRACT

A wavelength conversion system includes a first nonlinear optical crystal which first light having a first wavelength enters and from which second light having a second wavelength is output, a second nonlinear optical crystal which the second light and third light having a third wavelength enter and from which the third light and fourth light having a fourth wavelength are output, a third nonlinear optical crystal which the third light and the fourth light enter and from which fifth light having a fifth wavelength is output, and a light concentrating optical system configured to cause the first light to enter the first nonlinear optical crystal. Here, the first nonlinear optical crystal is located in a range within a Rayleigh length of the second light, and the third nonlinear optical crystal is located in a range within a Rayleigh length of the fourth light.

### CROSS-REFERENCE TO RELATED APPLICATIONS

The present application claims the benefit of International Application No. PCT/JP2022/039779, filed on Oct. 25, 2022, the entire contents of which are hereby incorporated by reference.

### BACKGROUND

### 1. Technical Field

The present disclosure relates to a wavelength conversion system, a solid-state laser system, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as the gas laser device for exposure, a KrF excimer laser device that outputs laser light having a wavelength of about 248 nm and an ArF excimer laser device that outputs laser light having a wavelength of about 193.4 nm are used.

The KrF excimer laser device and the ArF excimer laser device each have a large spectral line width of about 350 to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. A gas laser device with a narrowed spectral line width is referred to as a line narrowing gas laser device.

### LIST OF DOCUMENTS

### Patent Documents

Patent Document 1: U.S. Pat. No. 11,226,536
Patent Document 2: Japanese Patent Application Publication No. 2007-140564

### SUMMARY

A wavelength conversion system according to an aspect of the present disclosure includes a first nonlinear optical crystal which first light having a first wavelength enters and from which second light having a second wavelength and being a second harmonic of the first light is output, a second nonlinear optical crystal which the second light and third light having a third wavelength enter and from which the third light and fourth light having a fourth wavelength and being sum frequency light of the second light and the third light are output, a third nonlinear optical crystal which the third light and the fourth light enter and from which fifth light having a fifth wavelength and being sum frequency light of the third light and the fourth light is output, and a light concentrating optical system configured to cause the first light to enter the first nonlinear optical crystal so that a beam waist position of the second light is located in the second nonlinear optical crystal. Here, the first nonlinear optical crystal is located in a range within a Rayleigh length of the second light from the beam waist position of the second light, and the third nonlinear optical crystal is located in a range within a Rayleigh length of the fourth light from the beam waist position of the second light.

A solid-state laser system includes a wavelength conversion system including a first nonlinear optical crystal which first light having a first wavelength enters and from which second light having a second wavelength and being a second harmonic of the first light is output, a second nonlinear optical crystal which the second light and third light having a third wavelength enter and from which the third light and fourth light having a fourth wavelength and being sum frequency light of the second light and the third light are output, a third nonlinear optical crystal which the third light and the fourth light enter and from which fifth light having a fifth wavelength and being sum frequency light of the third light and the fourth light is output, and a light concentrating optical system configured to cause the first light to enter the first nonlinear optical crystal so that a beam waist position of the second light is located in the second nonlinear optical crystal; a signal laser device configured to output signal laser light; an amplification system configured to pulse-amplify the signal laser light based on pump laser light and output the pulse-amplified signal laser light to the wavelength conversion system as the third light; and a pump laser device configured to generate the pump laser light and the first light, output the pump laser light to the amplification system, and output the first light to the wavelength conversion system. Here, the first nonlinear optical crystal is located in a range within a Rayleigh length of the second light from the beam waist position of the second light, and the third nonlinear optical crystal is located in a range within a Rayleigh length of the fourth light from the beam waist position of the second light.

An electronic device manufacturing method according to an aspect of the present disclosure includes generating laser light using a solid-state laser system including a wavelength conversion system, outputting the laser light to an exposure apparatus, and exposing a photosensitive substrate to the laser light in the exposure apparatus to manufacture an electronic device. Here, the wavelength conversion system includes a first nonlinear optical crystal which first light having a first wavelength enters and from which second light having a second wavelength and being a second harmonic of the first light is output, a second nonlinear optical crystal which the second light and third light having a third wavelength enter and from which the third light and fourth light having a fourth wavelength and being sum frequency light of the second light and the third light are output, a third nonlinear optical crystal which the third light and the fourth light enter and from which fifth light having a fifth wavelength and being sum frequency light of the third light and the fourth light is output, and a light concentrating optical system configured to cause the first light to enter the first nonlinear optical crystal so that a beam waist position of the second light is located in the second nonlinear optical crystal. Here, the first nonlinear optical crystal is located in a range within a Rayleigh length of the second light from the beam waist position of the second light, and the third nonlinear optical crystal is located in a range within a Rayleigh length of the fourth light from the beam waist position of the second light.

### BRIEF DESCRIPTION OF THE DRAWINGS

Embodiments of the present disclosure will be described below merely as examples with reference to the accompanying drawings.

FIG. 1 is a diagram schematically showing the configuration of a solid-state laser system according to a comparative example.

FIG. 2 is a diagram schematically showing the configuration of a wavelength conversion system according to the comparative example.

FIG. 3 is a diagram schematically showing a cell in which a nonlinear optical crystal is arranged.

FIG. 4 is a diagram schematically showing the configuration of the wavelength conversion system according to a first embodiment.

FIG. 5 is a diagram showing the relationship between the Rayleigh length and a beam waist radius.

FIG. 6 is a diagram schematically showing the configuration of the wavelength conversion system according to a second embodiment.

FIG. 7 is a diagram schematically showing the configuration of a periscope optical system.

FIG. 8 is a diagram schematically showing the configuration of the wavelength conversion system according to a fourth embodiment.

FIG. 9 is a diagram schematically showing a configuration example of an exposure apparatus.

### DESCRIPTION OF EMBODIMENTS

### <Contents>

1. Comparative example
   1.1 Solid-state laser system
      1.1.1 Configuration
      1.1.2 Operation
   1.2 Wavelength conversion system
      1.2.1 Configuration and operation
   1.3 Problem
2. First Embodiment
   2.1 Configuration and operation
   2.2 Relationship between Rayleigh length and numerical aperture
   2.3 Effect
3. Second Embodiment
   3.1 Configuration and operation
   3.2 Effect
4. Third Embodiment
   4.1 Configuration and operation
   4.2 Effect
5. Fourth Embodiment
   5.1 Configuration and operation
   5.2 Effect
6. Electronic device manufacturing method

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

First, a comparative example of the present disclosure will be described. The comparative example of the present disclosure is an example recognized by the applicant as known only by the applicant, and is not a publicly known example admitted by the applicant.

### 1.1 Solid-State Laser System

### 1.1.1 Configuration

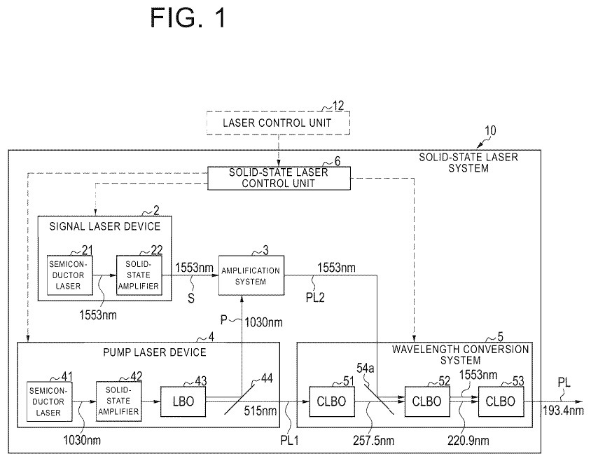

FIG. 1 schematically shows the configuration of a solid-state laser system 10 according to the comparative example. The solid-state laser system 10 includes a signal laser device 2, an amplification system 3, a pump laser device 4, a wavelength conversion system 5, and a solid-state laser control unit 6. The solid-state laser system 10 outputs pulse laser light having a wavelength of about 193.4 nm.

The signal laser device 2 includes a semiconductor laser 21 and a solid-state amplifier 22. The semiconductor laser 21 performs continuous wave (CW) oscillation in a single longitudinal mode, and outputs CW laser light having a wavelength of about 1553 nm. The solid-state amplifier 22 is an amplifier including a semiconductor optical amplifier, and amplifies the CW laser light output from the semiconductor laser 21. The CW laser light having a wavelength of about 1553 nm amplified by the solid-state amplifier 22 enters the amplification system 3 as signal laser light S.

The pump laser device 4 includes a semiconductor laser 41, a solid-state amplifier 42, an LBO (LiB₃O₅) crystal 43, and a dichroic mirror (DM) 44. The semiconductor laser 41 performs CW oscillation in a single longitudinal mode, and outputs CW laser light having a wavelength of about 1030 nm. The solid-state amplifier 42 is an amplifier including a semiconductor optical amplifier and a YAG crystal doped with Yb, and pulse-amplifies the CW laser light output from the semiconductor laser 41.

The LBO crystal 43 is a nonlinear optical crystal that converts a wavelength of the pulse laser light having a wavelength of about 1030 nm generated through pulse amplification by the solid-state amplifier 42, and generates pulse laser light having a wavelength of about 515 nm which is second harmonic.

The DM 44 is arranged downstream of the LBO crystal 43 so as to highly reflect the pulse laser light having a wavelength of about 1030 nm not having been wavelength-converted by the LBO crystal 43, and highly transmit the pulse laser light having a wavelength of about 515 nm incident from the LBO crystal 43. The pulse laser light highly reflected by the DM 44 is output from the pump laser device 4 and enters the amplification system 3 as pump laser light P. The pulse laser light highly transmitted through the DM 44 is output from the pump laser device 4 and enters the wavelength conversion system 5 as first pulse laser light PL1.

The amplification system 3 includes an optical parametric amplifier (OPA). The OPA is, for example, an amplifier including a periodically poled lithium niobate (PPLN) crystal, a periodically poled potassium titanyl phosphate (PPKTP) crystal, or the like. The OPA pulse-amplifies the signal laser light S entering from the signal laser device 2 based on the pump laser light P entering from the pump laser device 4. The pulse-amplified signal laser light S is output from the amplification system 3 and enters the wavelength conversion system 5 as second pulse laser light PL2.

The wavelength conversion system 5 includes a first CLBO (CsLiB₆O₁₀) crystal 51, a second CLBO crystal 52, a third CLBO crystal 53, and a DM 54a. The first CLBO crystal 51 is a nonlinear optical crystal that converts the wavelength of the first pulse laser light PL1 entering from the pump laser device 4 and generates and outputs ultraviolet pulse laser light having a wavelength of about 257.5 nm which is second harmonic of the first pulse laser light PL1.

The DM 54a is arranged downstream of the first CLBO crystal 51 so as to highly reflect the second pulse laser light PL2 incident from the amplification system 3 and highly transmit the ultraviolet pulse laser light incident from the first CLBO crystal 51. The DM 54a is arranged such that the highly reflected second pulse laser light PL2 and the highly transmitted ultraviolet pulse laser light coaxially enter the second CLBO crystal 52.

The second CLBO crystal 52 and the third CLBO crystal 53 are arranged in series, and generate and output the pulse laser light PL having a wavelength of about 193.4 nm by performing two times of sum frequency generation.

The solid-state laser control unit 6 is configured by a processor and is connected to the signal laser device 2, the pump laser device 4, and the wavelength conversion system 5. The solid-state laser control unit 6 is connected to a laser control unit 12 provided outside the solid-state laser system 10.

### 1.1.2 Operation

Next, operation of the solid-state laser system 10 according to the comparative example will be described. The solid-state laser control unit 6 controls a current value of the semiconductor laser 41 of the pump laser device 4 to cause CW oscillation, and causes the semiconductor laser 41 to output CW laser light having a wavelength of about 1030 nm. Further, the solid-state laser control unit 6 causes the solid-state amplifier 42 to pulse-amplify the CW laser light output from the semiconductor laser 41.

The LBO crystal 43 converts pulse laser light having a wavelength of about 1030 nm generated through pulse amplification by the solid-state amplifier 42 into pulse laser light having a wavelength of about 515 nm. The pulse laser light having a wavelength of about 515 nm is highly transmitted through the DM 44 and enters the wavelength conversion system 5 as the first pulse laser light PL1. Further, the pulse laser light having a wavelength of about 1030 nm not having been wavelength-converted by the LBO crystal 43 is highly reflected by the DM 44 and enters the amplification system 3 as the pump laser light P.

The solid-state laser control unit 6 controls a current value of the semiconductor laser 21 of the signal laser device 2 to cause CW oscillation, and causes the semiconductor laser 21 to output CW laser light having a wavelength of about 1553 nm. Further, the solid-state laser control unit 6 causes the solid-state amplifier 22 to amplify the CW laser light output from the semiconductor laser 21. Accordingly, the CW laser light having a wavelength of about 1553 nm is output from the signal laser device 2, and enters the amplification system 3 as the signal laser light S.

The amplification system 3 pulse-amplifies the signal laser light S based on the pump laser light P. The pulse-amplified signal laser light S enters the wavelength conversion system 5 as the second pulse laser light PL2.

In the wavelength conversion system 5, the first pulse laser light PL1 is converted into ultraviolet pulse laser light having a wavelength of about 257.5 nm by the first CLBO crystal 51. The ultraviolet pulse laser light having a wavelength of about 257.5 nm is highly transmitted through the DM 54a and enters the second CLBO crystal 52. The second pulse laser light PL2 is highly reflected by the DM 54a and enters the second CLBO crystal 52. The second CLBO crystal 52 generates and outputs ultraviolet pulse laser light having a wavelength of about 220.9 nm which is a sum frequency of the second pulse laser light PL2 and the ultraviolet pulse laser light having a wavelength of about 257.5 nm. Further, the second CLBO crystal 52 outputs the second pulse laser light PL2 not having been wavelength-converted.

The second pulse laser light PL2 output from the second CLBO crystal 52 and the ultraviolet pulse laser light having a wavelength of about 220.9 nm coaxially enter the third CLBO crystal 53. The third CLBO crystal 53 generates and outputs the pulse laser light PL having a wavelength of about 193.4 nm which is a sum frequency of the second pulse laser light PL2 and the ultraviolet pulse laser light having a wavelength of about 220.9 nm. The pulse laser light PL is output from the solid-state laser system 10.

The pulse laser light PL output from the solid-state laser system 10 may be amplified by an excimer amplifier (not shown).

### 1.2 Wavelength Conversion System

### 1.2.1 Configuration and Operation

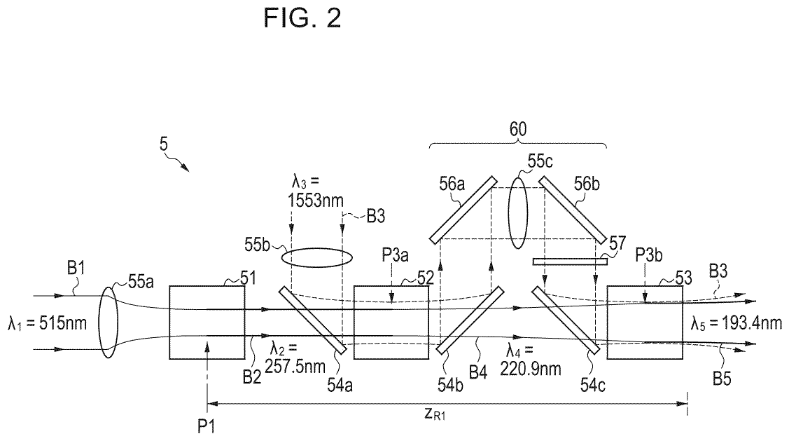

Next, the configuration and operation of the wavelength conversion system 5 according to the comparative example will be described in more detail with reference to FIG. 2. FIG. 2 shows the configuration of the wavelength conversion system 5 according to the comparative example. The wavelength conversion system 5 includes DMs 54b, 54c, lenses 55a to 55c, high reflection mirrors 56a, 56b, and a half wave plate 57 in addition to the first to third CLBO crystals 51 to 53 and the DM 54a described above.

The first to third CLBO crystals 51 to 53 are nonlinear optical crystals having a type-1 phase matching condition. That is, the first to third CLBO crystals 51 to 53 are each configured such that the angle formed between the optical axis thereof and the optical path axis of the entering laser light is a phase matching angle satisfying the type-1 phase matching condition.

The lens 55a is arranged on the optical path of first light B1 entering the wavelength conversion system 5 and upstream of the first CLBO crystal 51. The first light B1 is the first pulse laser light PL1 described above. A first wavelength 2 of the first light B1 is about 515 nm. The lens 55a concentrates the first light B1 such that a beam waist position P1 of the first light B1 is in the first CLBO crystal 51.

The first CLBO crystal 51 is arranged such that the crystal center is at the beam waist position P1. The first CLBO crystal 51 converts the first light B1 having the first wavelength λ₁ into second light B2 having a second wavelength λ₂ which is second harmonic of the first light B1, and outputs the second light B2. The second wavelength λ₂ is about 257.5 nm. The second light B2 is the above-described ultraviolet pulse laser light having a wavelength of about 257.5 nm. The first CLBO crystal 51 is an example of the “first nonlinear optical crystal” according to the technology of the present disclosure.

The beam waist position of the second light B2 is the same as the beam waist position P1 of the first light B1. That is, the second light B2 output from the first CLBO crystal 51 becomes diffused light diffused from the beam waist position P1.

The lens 55b is arranged on the optical path of third light B3 entering the wavelength conversion system 5 and upstream of the DM 54a. The third light B3 is the second pulse laser light PL2 described above. A third wavelength λ₃ of the third light B3 is about 1553 nm. The lens 55b concentrates the third light B3 via the DM 54a such that the beam waist position P3a of the third light B3 is in the second CLBO crystal 52.

The DM 54a is coated with a film that highly transmits the second light B2 and highly reflects the third light B3. The third light B3 incident on the DM 54a from the lens 55b and highly reflected by the DM 54a is concentrated in the second CLBO crystal 52.

The second CLBO crystal 52 is arranged such that the crystal center is at a beam waist position P3a. The second CLBO crystal 52 generates and outputs fourth light B4 that is sum frequency light of the second light B2 highly transmitted through the DM 54a and the third light B3 highly reflected by the DM 54a. A fourth wavelength 24 of the fourth light B4 is about 220.9 nm. Further, the second CLBO crystal 52 outputs the third light B3 not having been wavelength-converted. The second CLBO crystal 52 is an example of the “second nonlinear optical crystal” according to the technology of the present disclosure.

The second light B2 and the third light B3 that enter the second CLBO crystal 52 are both linearly polarized light. Since the second CLBO crystal 52 has the type-1 phase matching condition, the polarization directions of the second light B2 and the third light B3 entering the second CLBO crystal 52 need to be parallel to each other. When the polarization directions of the second light B2 and the third light B3 entering the second CLBO crystal 52 are parallel to each other, the polarization direction of the third light B3 output from the second CLBO crystal 52 is perpendicular to the polarization direction of the fourth light B4.

Since the third CLBO crystal 53 has the type-1 phase matching condition, the polarization directions of the third light B3 and the fourth light B4 entering the third CLBO crystal 53 need to be parallel to each other. Since the polarization directions of the third light B3 and the fourth light B4 output from the second CLBO crystal 52 are perpendicular to each other, the polarization direction of one of the third light B3 and the fourth light B4 needs to be rotated by 90°.

The DMs 54b, 54c, the lens 55c, the high reflection mirrors 56a, 56b, and the half wave plate 57 configure a polarization direction change optical system 60. The polarization direction change optical system 60 is arranged between the second CLBO crystal 52 and the third CLBO crystal 53. In the comparative example, the polarization direction change optical system 60 rotates the polarization direction of the third light B3 by 90°, so that the polarization directions of the third light B3 and the fourth light B4 are collimated with each other.

The DMs 54b, 54c are each coated with a film that highly transmits the fourth light B4 and highly reflects the third light B3. The DM 54b is an optical path branching element arranged downstream of the second CLBO crystal 52 and branches the optical paths of the third light B3 and the fourth light B4 output from the second CLBO crystal 52. The DM 54c is an optical path merging element arranged upstream of the third CLBO crystal 53 and merges the optical paths, branched by the DM 54b, of the third light B3 and the fourth light B4.

The DM 54b highly transmits the fourth light B4 output from the second CLBO crystal 52. The fourth light B4 highly transmitted through the DM 54b is highly transmitted through the DM 54c and enters the third CLBO crystal 53. The DM 54b highly reflects the third light B3 output from the second CLBO crystal 52.

The high reflection mirror 56a is arranged on the optical path of the third light B3 highly reflected by the DM 54b, and highly reflects the third light B3. The lens 55c is arranged downstream of the high reflection mirror 56a, and concentrates the third light B3 via the high reflection mirror 56a and the DM 54c so that a beam waist position P3b of the third light B3 highly reflected by the high reflection mirror 56a is in the third CLBO crystal 53.

The high reflection mirror 56b is arranged downstream of the lens 55c and highly reflects the third light B3. The half wave plate 57 is arranged downstream of the high reflection mirror 56b, and rotates the polarization direction of the third light B3 highly reflected by the high reflection mirror 56b by 90°.

The DM 54c is arranged downstream of the half wave plate 57, and highly reflects the third light B3 having the polarization direction rotated by 90° to enter the third CLBO crystal 53. As a result, the polarization directions of the third light B3 and the fourth light B4 entering the third CLBO crystal 53 are parallel to each other.

The third CLBO crystal 53 is arranged such that the crystal center is at the beam waist position P3b. The third CLBO crystal 53 generates and outputs fifth light B5 that is sum frequency light of the third light B3 and the fourth light B4. The fifth light B5 is the pulse laser light PL described above. A fifth wavelength λ₅ of the fifth light B5 is about 193.4 nm. The third CLBO crystal 53 is an example of the “third nonlinear optical crystal” according to the technology of the present disclosure. The first to fifth wavelengths λ₁ to λ₅ have a relationship of λ₃>λ₁>λ₂>λ₄>λ₅.

The second CLBO crystal 52 is arranged in a range in which the second light B2 that is the entering ultraviolet light can be regarded as parallel light. The third CLBO crystal 53 is arranged in a range in which the fourth light B4 that is the entering ultraviolet light can be regarded as parallel light. Since the second light B2 and the fourth light B4 are diffused light diffused from the beam waist position P1, the second CLBO crystal 52 and the third CLBO crystal 53 are located downstream from the beam waist position P1 in a range within a Rayleigh length z_{R1}. The Rayleigh length represents the distance at which pulse laser light can be regarded as parallel light.

### 1.3 Problem

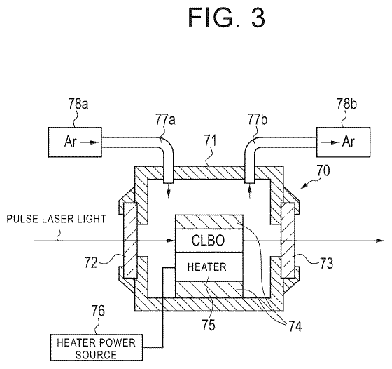

Next, a problem of the wavelength conversion system 5 according to the comparative example will be described. The nonlinear optical crystal such as a CLBO crystal is arranged inside a cell 70 as shown in FIG. 3 because it has hygroscopicity.

The cell 70 includes a housing 71, an inlet window 72, an outlet window 73, a crystal holder 74, and a heater 75. The inlet window 72 and the outlet window 73 are attached to the housing 71. The crystal holder 74 is provided inside the housing 71, and holds the nonlinear optical crystal on the optical path of the pulse laser light passing through the inlet window 72 and the outlet window 73. The heater 75 is attached to the crystal holder 74 and is connected to a heater power source 76 provided outside the cell 70. The heater 75 heats the nonlinear optical crystal.

A gas introduction pipe 77a for introducing a purge gas such as an Ar gas into the housing 71 and a gas discharge pipe 77b for discharging the purge gas from the inside of the housing 71 are connected to the housing 71. The gas introduction pipe 77a is connected to a gas supply device 78a. The gas discharge pipe 77b is connected to a gas discharge device 78b.

The cell 70 is used in a state in which the temperature of the nonlinear optical crystal is maintained at about 150° C. by the heater 75 while being purged with the purge gas. Therefore, to arrange the first to third CLBO crystals 51 to 53 in the wavelength conversion system 5, the optical path length for arranging the cells 70 must be ensured in front and behind the nonlinear optical crystals considering the volume of the cells 70.

z

It is conceivable to use a relay lens optical system to ensure the optical path length for arranging the cells 70. However, when the relay lens optical system is used, since the relay lens optical system has to propagate pulse laser light that is ultraviolet light, the lens deteriorates due to the ultraviolet light. As a result, the lifetime of the wavelength conversion system 5 is shortened. Further, since the thermal lens effect occurs due to absorption of the ultraviolet light by the lens, the beam diameter and the beam waist position are changed. Further, since surface reflection occurs at the lens, output of the pulse laser light decreases. For the above reasons, it is not preferable to use a relay lens optical system.

From the viewpoint of increasing efficiency of the wavelength conversion, it is preferable that the plurality of nonlinear optical crystals included in the wavelength conversion system 5 be arranged within the Rayleigh length from the beam waist position of the entering pulse laser light. In the example shown in FIG. 2, as described above, the second CLBO crystal 52 and the third CLBO crystal 53 are located in a range within the Rayleigh length z_{R1} downstream from the beam waist position P1 located at the crystal center of the first CLBO crystal 51.

However, considering also the volume of the cells 70, it is difficult to place each nonlinear optical crystal within the Rayleigh length. In the example shown in FIG. 2, considering the volume of the cells 70, it is difficult to arrange the second CLBO crystal 52 and the third CLBO crystal 53 within the Rayleigh length z_{R1} from the first CLBO crystal 51.

That is, the wavelength conversion system 5 having a plurality of nonlinear optical crystals such as CLBO crystals each having hygroscopicity has a problem in that the optical path length is too short for allowing the plurality of nonlinear optical crystals to be arranged from the viewpoint of increasing the efficiency of wavelength conversion and the degree of freedom in designing is very low.

### 2. First Embodiment

Next, a solid-state laser system 10 according to a first embodiment of the present disclosure will be described. The solid-state laser system 10 according to the first embodiment differs from the solid-state laser system 10 according to the comparative example only in the configuration of the wavelength conversion system. Hereinafter, the same components are denoted by the same numeral, and description thereof is appropriately omitted.

### 2.1 Configuration and Operation

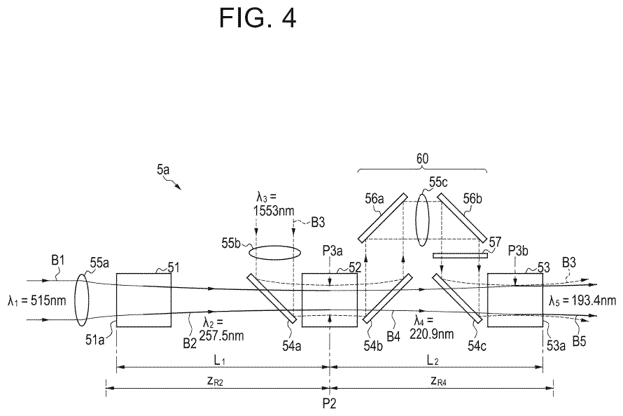

The configuration and operation of a wavelength conversion system 5a according to the first embodiment will be described with reference to FIG. 4. FIG. 4 shows the configuration of the wavelength conversion system 5a according to the first embodiment. The wavelength conversion system 5a includes the first to third CLBO crystals 51 to 53, the DMs 54a to 54c, the lenses 55a to 55c, the high reflection mirrors 56a, 56b, and the half wave plate 57, similarly to the wavelength conversion system 5 according to the comparative example.

In the present embodiment, the lens 55a causes the first light B1 to enter the first CLBO crystal 51 such that the beam waist position P2 of the second light B2 generated by the first CLBO crystal 51 is arranged in the second CLBO crystal 52. That is, owing to that the lens 55a concentrates the first light B1, the second light B2 is concentrated in the second CLBO crystal 52. The second CLBO crystal 52 is preferably arranged such that the crystal center is at the beam waist position P2. The lens 55a is an example of the “light concentrating optical system” according to the technology of the present disclosure. The light concentrating optical system is not limited to one lens, and may be configured by an optical system including two or more lenses, a mirror, and the like.

In the present embodiment, the beam waist position of the fourth light B4 generated by the second CLBO crystal 52 is the same as the beam waist position P2 of the second light B2. That is, the fourth light B4 output from the second CLBO crystal 52 becomes diffused light diffused from the beam waist position P2.

In the present embodiment, the first CLBO crystal 51 is arranged upstream of the second CLBO crystal 52 and within a Rayleigh length z_{R2} of the second light B2 from the beam waist position P2. Specifically, the first CLBO crystal 51 is arranged such that a surface 51a thereof on which light enters falls within the Rayleigh length z_{R2} of the second light B2 from the beam waist position P2.

Further, the third CLBO crystal 53 is arranged downstream of the second CLBO crystal 52 and within a Rayleigh length z_{R4} of the fourth light B4 from the beam waist position P2. Specifically, the third CLBO crystal 53 is arranged such that a surface 53a thereof from which light is output falls within the Rayleigh length z_{R4} of the fourth light B4 from the beam waist position P2.

### 2.2 Relationship Between Rayleigh Length and Numerical Aperture

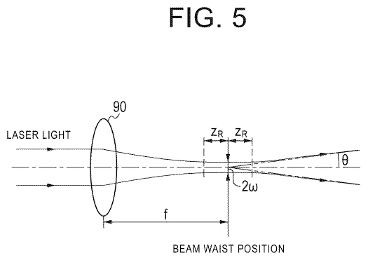

Next, description will be provided on the relationship between the Rayleigh length and the numerical aperture. FIG. 5 shows the relationship between a Rayleigh length z_{R} and a beam waist radius @ when laser light that is collimated light is incident on a lens 90.

The beam waist of the laser light concentrated by the lens 90 is generated at a position of the focal length f from the lens 90. The beam waist radius ω is the beam radius of the laser light at the beam waist position. More specifically, the beam waist radius ω is the beam radius at a position where the radiation intensity is 1/e² times of the peak radiation intensity at the beam center.

The relationship between the Rayleigh length z_{R} and the beam waist radius ω is expressed by following expression 1. Here, A is the wavelength of the parallel light incident on the lens 90.

$$[ Expression 1 ]$$

$${z}_{R} = \frac{{πω}^{2}}{λ} \qquad ( 1 )$$

The relationship between a numerical aperture NA and the beam waist radius ω is expressed by following expression 2. Here, n is the refractive index of the medium in which the laser light propagates. θ is the beam divergence angle.

$$[ Expression 2 ]$$

$$NA = n sin θ = n sin \frac{λ}{πω} \qquad ( 2 )$$

When n=1 and |θ|<<1, the above expression 2 is expressed by following expression 3.

$$[ Expression 3 ]$$

$$NA \approx \frac{λ}{πω} \qquad ( 3 )$$

Further, according to expression 1, the beam waist radius @ is expressed by following expression 4.

$$[ Expression 4 ]$$

$$ω = \sqrt{\frac{λ {z}_{R}}{π}} \qquad ( 4 )$$

As shown in FIG. 4, when the distance from the surface 51a of the first CLBO crystal 51 on which light is incident to the beam waist position P2 is L₁, following expression 5 needs to be satisfied to set the surface 51a on which light is incident falls within the Rayleigh length z_{R2} of the second light B2 from the beam waist position P2. Here, ω₂ is the beam waist radius of the second light B2.

$$[ Expression 5 ]$$

$${L}_{1} \leq {z}_{R 2} = \frac{{πω}_{2}^{2}}{{λ}_{2}} \qquad ( 5 )$$

According to expression 5, the beam waist radius ω₂ of the second light B2 needs to satisfy following expression 6.

$$[ Expression 6 ]$$

$${ω}_{2} \geq \sqrt{\frac{{λ}_{2} {L}_{1}}{π}} \qquad ( 6 )$$

According to expression 3 and expression 6, a numerical aperture NA₂ of the second light B2 is only required to satisfy following expression 7 to satisfy expression 5.

$$[ Expression 7 ]$$

$${NA}_{2} = \frac{{λ}_{2}}{{πω}_{2}} \leq \sqrt{\frac{{λ}_{2}}{π {L}_{1}}} \qquad ( 7 )$$

Further, as shown in FIG. 4, when the distance from a surface 53a of the third CLBO crystal 53 from which light is output to the beam waist position P2 is L₂, following expression 8 needs to be satisfied to make the surface 53a from which light is output fall within the Rayleigh length z_{R4} of the fourth light B4 from the beam waist position P2. Here, ω₄ is the beam waist radius of the fourth light B4.

$$[ Expression 8 ]$$

$${L}_{2} \leq {z}_{R 4} = \frac{{πω}_{4}^{2}}{{λ}_{4}} \qquad ( 8 )$$

Here, assuming that ω₄=ω₂, expression 8 is expressed by following expression 9.

$$[ Expression 9 ]$$

$${L}_{2} \leq {z}_{R 4} = \frac{{πω}_{4}^{2}}{{λ}_{4}} = \frac{{πω}_{2}^{2}}{{λ}_{4}} \qquad ( 9 )$$

Further, it is assumed that the beam waist position of the first light B1 matches to the beam waist position P2 of the second light B2 and the beam waist radius ω₁ of the first light B1 satisfies following expression 10.

$$[ Expression 10 ]$$

$${ω}_{1} = \sqrt{2} {ω}_{2} \qquad ( 10 )$$

Here, a numerical aperture NA₁ of the first light B1 is expressed by following expression 11.

$$[ Expression 11 ]$$

$${NA}_{1} = \frac{{λ}_{1}}{{πω}_{1}} = \frac{2 {λ}_{2}}{π \sqrt{2} {ω}_{2}} = \sqrt{2} {NA}_{2} \qquad ( 11 )$$

Therefore, in the present embodiment, it is only required that the beam waist radius ω₂ of the second light B2 is set to satisfy expression 6 with respect to the distance L₁ and the numerical aperture NA₂ of the second light B2 is set to satisfy expression 7. Further, the lens 55a for concentrating the first light B1 is only required that the beam waist radius ω₁ of the first light B1 satisfies expression 10 and the numerical aperture NA₁ is √2 times the numerical aperture NA₂ of the second light B2.

That is, it is only required to select a lens, as the lens 55a, having the numerical aperture NA₁ expressed by following expression 12.

$$[ Expression 12 ]$$

$${NA}_{1} \leq \sqrt{\frac{2 {λ}_{2}}{π {L}_{1}}} \qquad ( 12 )$$

### 2.3 Effect

As described above, in the wavelength conversion system 5a according to the present embodiment, the lens 55a causes the first light B1 to enter the first CLBO crystal 51 such that the beam waist position P2 of the second light B2 generated by the first CLBO crystal 51 is arranged in the second CLBO crystal 52. Therefore, the first CLBO crystal 51 can be arranged upstream from the beam waist position P2 within the Rayleigh length z_{R2} of the second light B2. Further, the third CLBO crystal 53 can be arranged downstream from the beam waist position P2 within the Rayleigh length z_{R4} of the fourth light B4. By arranging all of the first to third CLBO crystals 51 to 53 within the optical path length range defined by the Rayleigh lengths z_{R2}, z_{R4} from the beam waist position P2, the wavelength conversion efficiency is improved.

As described above, according to the present embodiment, since the optical path length that allows a plurality of nonlinear optical crystals to be arranged from the viewpoint of improving the efficiency of wavelength conversion is increased, it is possible to improve the flexibility of designing the wavelength conversion system 5a without lowering the wavelength conversion efficiency. As a result, each of the plurality of nonlinear optical crystals can be arranged inside the cell without using a relay lens optical system.

### 3. Second Embodiment

Next, a solid-state laser system 10 according to a second embodiment of the present disclosure will be described. The solid-state laser system 10 according to the second embodiment differs from the solid-state laser system 10 according to the first embodiment only in the configuration of the wavelength conversion system. Hereinafter, the same component as that in the first embodiment is denoted by the same reference numeral, and description thereof will be omitted as appropriate.

### 3.1 Configuration and Operation

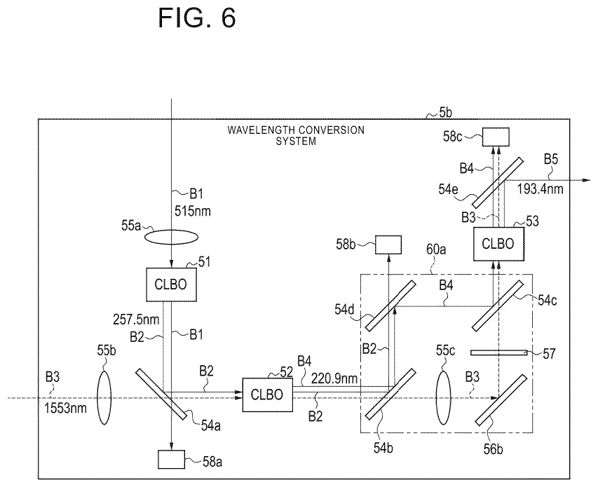

The configuration and operation of a wavelength conversion system 5b according to the second embodiment will be described with reference to FIG. 6. FIG. 6 shows the configuration of the wavelength conversion system 5b according to the second embodiment. The wavelength conversion system 5b includes the first to third CLBO crystals 51 to 53, the DMs 54a to 54e, the lenses 55a to 55c, the high reflection mirror 56b, the half wave plate 57, and dampers 58a to 58c. As in the first embodiment, the first to third CLBO crystals 51 to 53 are nonlinear optical crystals each having the type-1 phase matching condition.

In the first embodiment, the first to third CLBO crystals 51 to 53 are arranged on a straight line, but in the present embodiment, the first to third CLBO crystals 51 to 53 are arranged on a non-straight line. Further, in the present embodiment, the light not having been wavelength-converted by the first to third CLBO crystals 51 to 53 is absorbed by the dampers 58a to 58c.

In the present embodiment as well, the lens 55a causes the first light B1 to enter the first CLBO crystal 51 such that the beam waist position P2 of the second light B2 generated by the first CLBO crystal 51 is arranged in the second CLBO crystal 52. The first CLBO crystal 51 is located upstream from the beam waist position P2 in a range within the Rayleigh length z_{R2} of the second light B2. Further, the third CLBO crystal 53 is arranged downstream from the beam waist position P2 in a range within the Rayleigh length z_{R4} of the fourth light B4. When the optical paths of the second light B2 and the fourth light B4 are bent as in the present embodiment, the Rayleigh lengths z_{R2}, z_{R4} are each defined by the optical path length along the bent optical path.

In the present embodiment, the DM 54a is coated with a film that highly reflects the second light B2 and highly transmits the first light B1 and the third light B3. The second light B2 is generated by the first CLBO crystal 51 after entering the first CLBO crystal 51 from the lens 55a is highly reflected by the DM 54a and concentrated in the second CLBO crystal 52. The third light B3 incident on the DM 54a from the lens 55b is highly transmitted through the DM 54a and concentrated in the second CLBO crystal 52.

The damper 58a is arranged on the optical path of the first light B1 not wavelength-converted by the first CLBO crystal 51 and highly transmitted through the DM 54a, and absorbs the first light B1.

The second CLBO crystal 52 is arranged on the optical paths of the second light B2 highly reflected by the DM 54a and the third light B3 highly transmitted through the DM 54a. As in the first embodiment, the second CLBO crystal 52 generates the fourth light B4 that is sum frequency light of the second light B2 and the third light B3.

In the present embodiment, the DMs 54b to 54d, the lens 55c, the high reflection mirror 56b, and the half wave plate 57 configure a polarization direction change optical system 60a. The polarization direction change optical system 60a receives the fourth light B4 output from the second CLBO crystal 52, and the second light B2 and the third light B3 not wavelength-converted by the second CLBO crystal 52.

As in the first embodiment, the DM 54b is an optical path branching element. In the present embodiment, the DM 54b is arranged downstream of the second CLBO crystal 52, highly reflects the second light B2 and the fourth light B4, and highly transmits the third light B3.

The DM 54d is arranged on the optical paths of the second light B2 and the fourth light B4 highly reflected by the DM 54b, and highly reflects the fourth light B4 and highly transmits the second light B2. The damper 58b is arranged on the optical path of the second light B2 highly transmitted through the DM 54d, and absorbs the second light B2.

The lens 55c is arranged on the optical path of the third light B3 highly transmitted through the DM 54b, and concentrates the third light B3 in the third CLBO crystal 53. The high reflection mirror 56b is arranged downstream of the lens 55c and highly reflects the third light B3. The half wave plate 57 is arranged downstream of the high reflection mirror 56b, and rotates the polarization direction of the third light B3 highly reflected by the high reflection mirror 56b by 90°.

As in the first embodiment, the DM 54c is an optical path merging element. In the present embodiment, the DM 54c is arranged downstream of the half wave plate 57, and highly transmits the third light B3 having the polarization direction rotated by 90° to enter the third CLBO crystal 53. Further, the DM 54c is arranged on the optical path of the fourth light B4 highly reflected by the DM 54d, and highly reflects the fourth light B4 to enter the third CLBO crystal 53.

The third CLBO crystal 53 generates and outputs the fifth light B5 that is sum frequency light of the third light B3 and the fourth light B4. The DM 54e is arranged downstream of the third CLBO crystal 53, highly reflects the fifth light B5, and highly transmits the third light B3 and the fourth light B4. The damper 58c is arranged on the optical paths of the third light B3 and the fourth light B4 highly transmitted through the DM 54e, and absorbs the third light B3 and the fourth light B4.

In the DMs 54a to 54e, the relationship between reflection and transmission may be opposite to the relationship described above. That is, the arrangement of the plurality of components included in the wavelength conversion system 5b can be variously modified.

### 3.2 Effect

According to the wavelength conversion system 5b of the present embodiment, similarly to the wavelength conversion system 5a of the first embodiment, the optical path length that allows a plurality of nonlinear optical crystals to be arranged from the viewpoint of improving the efficiency of wavelength conversion is increased. Accordingly, since the degree of freedom in designing is improved, the dichroic mirrors, the dampers, and the like can be efficiently arranged.

### 4. Third Embodiment

Next, a solid-state laser system 10 according to a third embodiment of the present disclosure will be described. The solid-state laser system 10 according to the third embodiment differs from the solid-state laser system 10 according to the first embodiment only in the configuration of the wavelength conversion system.

### 4.1 Configuration and Operation

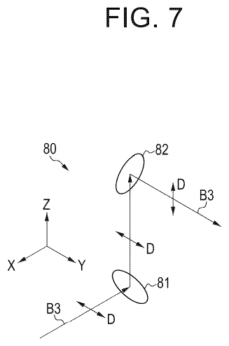

The wavelength conversion system according to the present embodiment includes a periscope optical system 80 shown in FIG. 7 in place of the half wave plate 57 included in the polarization direction change optical system 60 of the wavelength conversion system 5a according to the first embodiment. In FIG. 7, a reference numeral D denotes the polarization direction of the third light B3. Here, the X direction, the Y direction, and the Z direction are directions orthogonal to one another.

The periscope optical system 80 includes a first periscope mirror 81 and a second periscope mirror 82. The first periscope mirror 81 is arranged on the optical path of the third light B3, and deflects the optical path by 90° by highly reflecting the third light B3. The second periscope mirror 82 is arranged on the optical path of the third light B3 highly reflected by the first periscope mirror 81, and deflects the optical path by 90° by highly reflecting the third light B3. The second periscope mirror 82 is arranged to reflect the third light B3 in a direction perpendicular to the direction of incidence of the third light B3 on the first periscope mirror 81.

The third light B3 travels in the X direction to be incident on the first periscope mirror 81, and is highly reflected in the Z direction by the first periscope mirror 81. At this time, the polarization direction D of the third light B3 is the Y direction. The optical path of the third light B3 is changed by being highly reflected by the first periscope mirror 81, but the polarization direction D is not changed. The third light B3 highly reflected by the first periscope mirror 81 travels in the Z direction to be incident on the second periscope mirror 82, and is highly reflected by the second periscope mirror 82 in the Y direction. The polarization direction D is rotated by 90° by being highly reflected by the second periscope mirror 82.

Thus, the periscope optical system 80 can rotate the polarization direction of the third light B3 by 90° similarly to the half wave plate 57. Here, the periscope optical system 80 may be configured using three or more periscope mirrors.

### 4.2 Effect

Since the half wave plate 57 is a light transmission element, there is a possibility that the polarization direction is influenced by thermal load. On the other hand, since the periscope optical system 80 is configured by periscope mirrors being light reflection elements, thermal load is less likely to occur and influence of the thermal load on the polarization direction can be suppressed.

Here, the periscope optical system 80 may be used in place of the half wave plate 57 included in the polarization direction change optical system 60a of the wavelength conversion system 5b according to the second embodiment.

### 5. Fourth Embodiment

Next, a solid-state laser system 10 according to a fourth embodiment of the present disclosure will be described. The solid-state laser system 10 according to the fourth embodiment differs from the solid-state laser system 10 according to the second embodiment only in the configuration of the wavelength conversion system. Hereinafter, the same component as that in the second embodiment is denoted by the same reference numeral, and description thereof will be omitted as appropriate.

### 5.1 Configuration and Operation

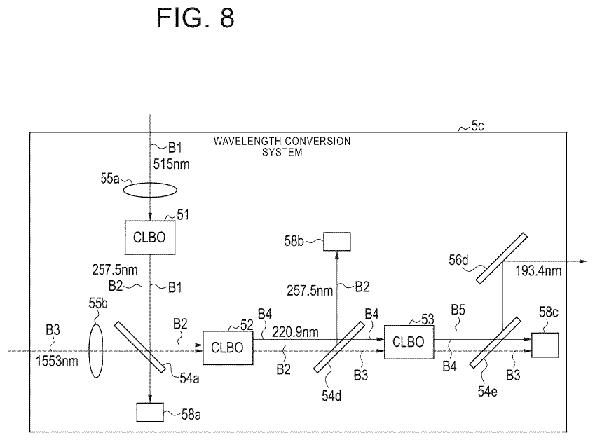

The configuration and operation of a wavelength conversion system 5c according to the fourth embodiment will be described with reference to FIG. 8. FIG. 8 shows the configuration of the wavelength conversion system 5c according to the fourth embodiment. The wavelength conversion system 5c includes the first to third CLBO crystals 51 to 53, the DMs 54a, 54d, 54e, the lenses 55a, 55b, the high reflection mirror 56d, and the dampers 58a to 58c.

In the present embodiment, the first CLBO crystal 51 and the third CLBO crystal 53 are nonlinear optical crystals each having the type-1 phase matching condition. The second CLBO crystal 52 is a nonlinear optical crystal having a type-2 phase matching condition. The second CLBO crystal 52 is configured such that the angle formed between the optical axis thereof and the optical path axis of the entering laser light is a phase matching angle satisfying the type-2 phase matching condition.

In the present embodiment, since the second CLBO crystal 52 has the type-2 phase matching condition, the polarization directions of the second light B2 and the third light B3 entering the second the second CLBO crystal 52 are orthogonally oriented. Accordingly, since the polarization directions of the third light B3 and the fourth light B4 output from the second CLBO crystal 52 become parallel to each other, there is no need to provide the polarization direction change optical system 60a as in the second embodiment.

Therefore, the wavelength conversion system 5c is not provided with the polarization direction change optical system 60a. The DM 54d that highly reflects the second light B2 and highly transmits the third light B3 and the fourth light B is arranged downstream of the second CLBO crystal 52. The third light B3 and the fourth light B4 highly transmitted through the DM 54d enter the third CLBO crystal 53 with their polarization directions parallel to each other. The damper 58b is arranged on the optical path of the second light B2 highly reflected by the DM 54d, and absorbs the second light B2.

The DM 54e is arranged downstream of the third CLBO crystal 53, highly reflects the fifth light B5, and highly transmits the third light B3 and the fourth light B4. The high reflection mirror 56d is arranged on the optical path of the fifth light B5 highly reflected by the DM 54e, and highly reflects the fifth light B5.

In the present embodiment, since the lens 55c is not provided, the lens 55b is configured to concentrate the third light B3 between the second CLBO crystal 52 and the third CLBO crystal 53.

Other configurations of the wavelength conversion system 5c are similar to those of the wavelength conversion system 5b. In the DMs 54a, 54d, 54e, the relationship between reflection and transmission may be opposite to the relationship described above. That is, the arrangement of the plurality of components included in the wavelength conversion system 5c can be variously modified. Here, the high reflection mirror 56d is not an essential component.

### 5.2 Effect

In the present embodiment, since the second CLBO crystal 52 is a nonlinear optical crystal having the type-2 phase matching condition, the half wave plate 57 does not need to be provided as in the second embodiment. Accordingly, the influence of the thermal load on the polarization direction can be suppressed.

### 6. Electronic Device Manufacturing Method

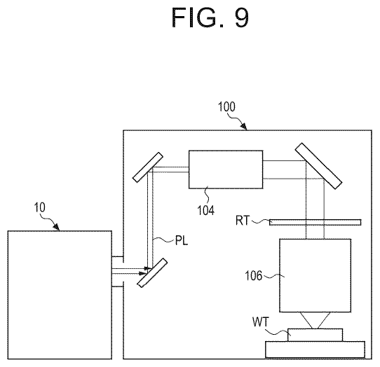

FIG. 9 schematically shows a configuration example of an exposure apparatus 100. The exposure apparatus 100 includes an illumination optical system 104 and a projection optical system 106. For example, the illumination optical system 104 illuminates a reticle pattern of a reticle (not shown) arranged on a reticle stage RT with the pulse laser light PL incident from the solid-state laser system 10. The projection optical system 106 causes the pulse laser light PL transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 100 synchronously translates the reticle stage RT and the workpiece table WT to expose the workpiece to the pulse laser light PL reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A wavelength conversion system comprising:
a first nonlinear optical crystal which first light having a first wavelength enters and from which second light having a second wavelength and being a second harmonic of the first light is output;
a second nonlinear optical crystal which the second light and third light having a third wavelength enter and from which the third light and fourth light having a fourth wavelength and being sum frequency light of the second light and the third light are output;
a third nonlinear optical crystal which the third light and the fourth light enter and from which fifth light having a fifth wavelength and being sum frequency light of the third light and the fourth light is output; and
a light concentrating optical system configured to cause the first light to enter the first nonlinear optical crystal so that a beam waist position of the second light is located in the second nonlinear optical crystal,
the first nonlinear optical crystal being located in a range within a Rayleigh length of the second light from the beam waist position of the second light, and
the third nonlinear optical crystal being located in a range within a Rayleigh length of the fourth light from the beam waist position of the second light.

2. The wavelength conversion system according to claim 1,
wherein following expression 1 is satisfied where a numerical aperture of the light concentrating optical system is NA₁, the second wavelength is λ₂, and a distance from the beam waist position of the second light to a surface of the first nonlinear optical crystal on which the first light is incident is L₁
$$[ Expression 1 ]$$
$${NA}_{1} \leq \sqrt{\frac{2 {λ}_{2}}{π {L}_{1}}} . \qquad ( 1 )$$

3. The wavelength conversion system according to claim 1,
wherein the first nonlinear optical crystal, the second nonlinear optical crystal, and the third nonlinear optical crystal each have a type-1 phase matching condition,
the second light and the third light entering the second nonlinear optical crystal are linearly polarized light and polarization directions thereof are parallel to each other, and
the wavelength conversion system includes a polarization direction change optical system configured to rotate the polarization direction of the third light entering the third nonlinear optical crystal by 90°.

4. The wavelength conversion system according to claim 3,
wherein the polarization direction change optical system includes a half wave plate configured to rotate the polarization direction of the third light by 90°.

5. The wavelength conversion system according to claim 3,
wherein the polarization direction change optical system includes a periscope optical system configured to rotate the polarization direction of the third light by 90°.

6. The wavelength conversion system according to claim 1,
wherein the first nonlinear optical crystal and the third nonlinear optical crystal each have a type-1 phase matching condition,
the second nonlinear optical crystal has a type-2 phase matching condition, and
the second light and the third light entering the second nonlinear optical crystal are linearly polarized light and polarization directions thereof are perpendicular to each other.

7. The wavelength conversion system according to claim 1,
wherein the first nonlinear optical crystal, the second nonlinear optical crystal, and the third nonlinear optical crystal are CLBO crystals.

8. The wavelength conversion system according to claim 1,
wherein the third wavelength is longer than the first wavelength, the first wavelength is longer than the second wavelength, the second wavelength is longer than the fourth wavelength, and the fourth wavelength is longer than the fifth wavelength.

9. A solid-state laser system comprising:
a wavelength conversion system including:
a first nonlinear optical crystal which first light having a first wavelength enters and from which second light having a second wavelength and being a second harmonic of the first light is output;
a second nonlinear optical crystal which the second light and third light having a third wavelength enter and from which the third light and fourth light having a fourth wavelength and being sum frequency light of the second light and the third light are output;
a third nonlinear optical crystal which the third light and the fourth light enter and from which fifth light having a fifth wavelength and being sum frequency light of the third light and the fourth light is output; and
a light concentrating optical system configured to cause the first light to enter the first nonlinear optical crystal so that a beam waist position of the second light is located in the second nonlinear optical crystal,
the first nonlinear optical crystal being located in a range within a Rayleigh length of the second light from the beam waist position of the second light, and
the third nonlinear optical crystal being located in a range within a Rayleigh length of the fourth light from the beam waist position of the second light,
a signal laser device configured to output signal laser light;
an amplification system configured to pulse-amplify the signal laser light based on pump laser light and output the pulse-amplified signal laser light to the wavelength conversion system as the third light; and
a pump laser device configured to generate the pump laser light and the first light, output the pump laser light to the amplification system, and output the first light to the wavelength conversion system.

10. An electronic device manufacturing method, comprising:
generating laser light using a solid-state laser system including a wavelength conversion system;
outputting the laser light to an exposure apparatus; and
exposing a photosensitive substrate to the laser light in the exposure apparatus to manufacture an electronic device,
the wavelength conversion system including:
a first nonlinear optical crystal which first light having a first wavelength enters and from which second light having a second wavelength and being a second harmonic of the first light is output;
a second nonlinear optical crystal which the second light and third light having a third wavelength enter and from which the third light and fourth light having a fourth wavelength and being sum frequency light of the second light and the third light are output;
a third nonlinear optical crystal which the third light and the fourth light enter and from which fifth light having a fifth wavelength and being sum frequency light of the third light and the fourth light is output; and
a light concentrating optical system configured to cause the first light to enter the first nonlinear optical crystal so that a beam waist position of the second light is located in the second nonlinear optical crystal,
the first nonlinear optical crystal being located in a range within a Rayleigh length of the second light from the beam waist position of the second light, and
the third nonlinear optical crystal being located in a range within a Rayleigh length of the fourth light from the beam waist position of the second light.
